(19) United States
(12) Patent Application Publication
(10) Pub. No.: US 2024/0380368 A1
(43) Pub. Date: Nov. 14, 2024

(54) LIMITER CIRCUIT AND POWER AMPLIFIER CIRCUIT

(71) Applicant: Murata Manufacturing Co., Ltd., Kyoto (JP)

(72) Inventor: Yoshifumi TAKAHASHI, Kyoto (JP)

(21) Appl. No.: 18/783,826

(22) Filed: Jul. 25, 2024

Related U.S. Application Data
(63) Continuation of application No. PCT/JP2023/005045, filed on Feb. 14, 2023.

(30) Foreign Application Priority Data
Feb. 14, 2022 (JP) 2022-020862

(51) Int. Cl. H03F 1/52; H03F 3/24

(52) U.S. Cl. CPC H03F 1/52; H03F 3/245; H03F 2200/426; H03F 2200/451

(57) ABSTRACT

There is provided a limiter circuit and a power amplifier circuit that are capable of effectively limiting output power of an amplifying transistor based on the amplitude of an input signal. A limiter circuit is connectable to an amplifying transistor that amplifies and outputs a radio frequency signal and controls a voltage to be applied to the amplifying transistor, based on the radio frequency signal. The limiter circuit includes an input signal detection transistor that detects power of the radio frequency signal and a voltage limiting transistor that limits the voltage to be applied to the amplifying transistor, based on current flowing to the input signal detection transistor.

### CROSS REFERENCE TO RELATED APPLICATION

This is a continuation of International Application No. PCT/JP2023/005045 filed on Feb. 14, 2023, which claims priority from Japanese Patent Application No. 2022-020862 filed on Feb. 14, 2022. The contents of these applications are incorporated herein by reference in their entireties.

### BACKGROUND ART

### Technical Field

The present disclosure relates to a limiter circuit and a power amplifier circuit.

There are an envelope tracking (ET) system and an average power tracking (APT) system as technology for enhancing efficiency for a power amplifier circuit included in a wireless communication terminal. In the ET system, amplifier circuits with a plurality of stages are connected in a multi-stage connection configuration, and power efficiency is improved by controlling the supply voltage of each amplifier circuit based on the amplitude level of an input signal. In the APT system, power efficiency is improved by controlling the supply voltage of an amplifier circuit based on average output power.

The amplifier circuits with the plurality of stages are formed from, for example, bipolar transistors or field effect transistors (FETs). An excessive increase in the output power of an amplifier circuit at the previous stage possibly leads to over input to an amplifier circuit at the subsequent stage. For example, a limiter circuit that limits output power is disclosed (for example, Patent Document 1), the output power being limited in such a manner that a bias voltage is applied to the drain of a FET via a resistor and bias current is limited with the increase of an input signal supplied to a control electrode.

Patent Document 1: Japanese Unexamined Patent Application Publication No. 4-294621

### BRIEF SUMMARY

If the limiter circuit described in Patent Document 1 is applied to a configuration for controlling the supply voltage of an amplifier circuit, there is a possibility that an increase in a supply voltage countervails a bias current limitation effect involved with the increase of an input signal is cancelled each other and thus a sufficient output power reduction effect is not provided.

The present disclosure provides a limiter circuit and a power amplifier circuit that are capable of effectively limiting the output power of an amplifying transistor based on the amplitude of an input signal.

A limiter circuit according to an aspect of the present disclosure is connectable to an amplifying transistor that amplifies and outputs a radio frequency signal, the limiter circuit controlling a voltage to be applied to the amplifying transistor, the limiter circuit controlling the voltage based on the radio frequency signal. The limiter circuit includes: an input signal detection transistor that detects power of the radio frequency signal; and a voltage limiting transistor that limits the voltage to be applied to the amplifying transistor, the voltage limiting transistor limiting the voltage based on current flowing to the input signal detection transistor.

An limiter circuit according to an aspect of the present disclosure includes: an input terminal; an output terminal; an input signal detection transistor that is electrically connected to the input terminal and that detects power of a radio frequency signal; and a voltage limiting transistor having a first terminal electrically connected to the output terminal and a third terminal electrically connected to a first supply voltage terminal. An amplifying transistor that amplifies and outputs a radio frequency signal is connectable between the input terminal and the output terminal.

A power amplifier circuit according to an aspect of the present disclosure includes: the limiter circuit described above; and an amplifying transistor that is provided between the input terminal and the output terminal and that amplifies and outputs a radio frequency signal.

A power amplifier circuit according to an aspect of the present disclosure is a power amplifier circuit in which a plurality of amplifier circuits are connected in a multi-stage connection configuration. At least one of the plurality of amplifier circuits except an amplifier circuit at a last stage includes: the limiter circuit described above; and an amplifying transistor that is provided between the input terminal and the output terminal and that amplifies and outputs a radio frequency signal.

The present disclosure enables, to be provided, a limiter circuit and a power amplifier circuit that are capable of effectively limiting the output power of an amplifying transistor based on the amplitude of an input signal.

### BRIEF DESCRIPTION OF THE DRAWINGS

FIG. 1A is a view illustrating a first example of the schematic configuration of a power amplifier circuit according to the present disclosure.

FIG. 1B is a view illustrating a second example of the schematic configuration of a power amplifier circuit according to the present disclosure.

FIG. 2 is a view illustrating an example configuration of an amplifier circuit to which a limiter circuit according to an embodiment is applied.

FIG. 3A is a graph illustrating an example of a characteristic of current flowing to the limiter circuit relative to the input power amplitude of an amplifying transistor.

FIG. 3B is a graph illustrating an example of an input-output power characteristic of the amplifying transistor.

FIG. 4 is a graph illustrating an example configuration of an amplifier circuit according to a comparative example.

FIG. 5 is a graph illustrating an example input-output power characteristic of the amplifier circuit according to the comparative example.

FIG. 6A is a graph illustrating a first setting example of a limiting characteristic in the limiter circuit according to the embodiment.

FIG. 6B is a graph illustrating the first setting example of the limiting characteristic in the limiter circuit according to the embodiment.

FIG. 7A is a graph illustrating a second setting example of the limiting characteristic in the limiter circuit according to the embodiment.

FIG. 7B is a graph illustrating the second setting example of the limiting characteristic in the limiter circuit according to the embodiment.

FIG. 8 is a view illustrating an example configuration of an amplifier circuit to which a limiter circuit according to a first modification of the embodiment is applied.

FIG. 9 is a view illustrating an example configuration of an amplifier circuit to which a limiter circuit according a second modification of the embodiment is applied.

FIG. 10 is a view illustrating an example configuration of an amplifier circuit to which a limiter circuit according a third modification of the embodiment is applied.

FIG. 11 is a view illustrating an example configuration of an amplifier circuit to which a limiter circuit according a fourth modification of the embodiment is applied.

FIG. 12 is a view illustrating an example configuration of an amplifier circuit to which a limiter circuit according a fifth modification of the embodiment is applied.

FIG. 13 is a view illustrating an example configuration of an amplifier circuit to which a limiter circuit according a sixth modification of the embodiment is applied.

FIG. 14A is a view illustrating an example configuration of an amplifier circuit to which a limiter circuit according a seventh modification of the embodiment is applied.

FIG. 14B is a view illustrating an example configuration of the amplifier circuit to which the limiter circuit according to the seventh modification of the embodiment is applied.

FIG. 15A is a graph illustrating an improvement example of a limiting characteristic in the limiter circuit according to the seventh modification of the embodiment.

FIG. 15B is a graph illustrating an improvement example of the limiting characteristic in the limiter circuit according to the seventh modification of the embodiment.

FIG. 16A is a view illustrating an example configuration of an amplifier circuit to which the limiter circuit according to an eighth modification of the embodiment is applied.

FIG. 16B is a view illustrating an example configuration of the amplifier circuit to which the limiter circuit according to the eighth modification of the embodiment is applied.

### DETAILED DESCRIPTION

Hereinafter, a limiter circuit and a power amplifier circuit according to an embodiment will be described in detail based on the drawings. Note that the present disclosure is not limited to the embodiment. The embodiment and modifications are provided as examples, and it goes without necessarily saying that configurations described in the embodiment and the modifications are partially replaced with or combined with each other. For the modifications of the embodiment, description of any matter common to that in the embodiment is omitted, and one or more different points only will be described. The same actions and effects of the same configuration are not particularly referred to for each modification.

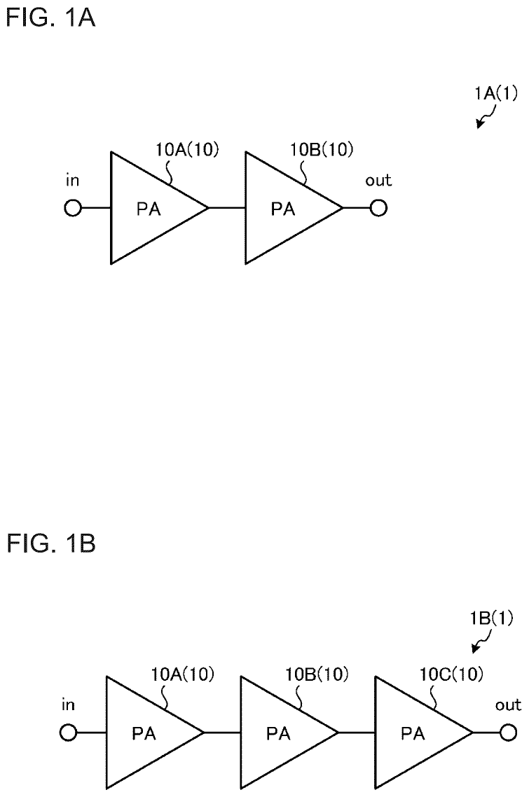

FIG. 1A is a view illustrating a first example of the schematic configuration of a power amplifier circuit according to the present disclosure. FIG. 1B is a view illustrating a second example of the schematic configuration of a power amplifier circuit according to the present disclosure. A power amplifier circuit 1 according to the present disclosure is included in a wireless communication terminal that supports, for example, 5-GHz-band radio frequency communication using Sub6 or WiFi in fifth generation mobile communication systems.

As illustrated in FIG. 1A and FIG. 1B, the power amplifier circuit 1 (each of 1A and 1B) according to the present disclosure has a configuration in which amplifier circuits 10 with a plurality of stages are connected in series. In the present disclosure, the power amplifier circuit 1 amplifies a radio frequency signal in a transmission frequency band having a predetermined band width including one or more bands (multi-band), appropriately for, for example, a communication system supported by a wireless communication terminal.

FIG. 1A illustrates a power amplifier circuit 1A having a two-stage configuration in which two amplifier circuits 10A and 10B are connected in series. FIG. 1B illustrates a power amplifier circuit 1B having a three-stage configuration in which three amplifier circuits that are the amplifier circuits 10A and 10B and an amplifier circuit 10C are connected in series. The configuration of the power amplifier circuit 1 is not limited to the two-stage configuration and the three-stage configuration and may be a multi-stage configuration in which four or more amplifier circuits 10 are connected in series.

The power amplifier circuit 1 receives an input signal that is a radio frequency signal in a transmission frequency band from a circuit at the previous stage connected to an input terminal in and amplifies the input signal. The power amplifier circuit 1 outputs an output signal that is the radio frequency signal after the amplification to a circuit at the subsequent stage connected to an output terminal out. A transmission power control circuit that controls the power of a modulated signal is exemplified as the circuit at the previous stage, but the circuit at the previous stage is not limited to this. A frontend circuit that performs filtering or the like for an output signal and transmits the output signal to an antenna is exemplified as the circuit at the subsequent stage, but the circuit at the subsequent stage is not limited to this.

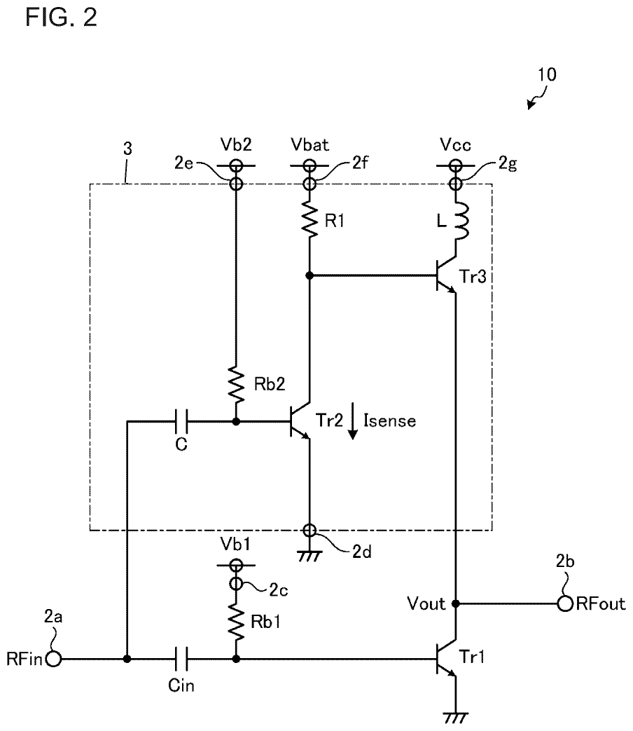

An excessive increase in the output power of the amplifier circuit 10A at the previous stage in the power amplifier circuit 1A having the two-stage configuration illustrated in FIG. 1A possibly leads to over input to the amplifier circuit 10B at the subsequent stage. An excessive increase in the output power of the amplifier circuit 10A at the previous stage in the power amplifier circuit 1B of the three-stage configuration illustrated in FIG. 2B possibly leads to over input to the amplifier circuit 10B at the subsequent stage. Likewise, an excessive increase in the output power of the amplifier circuit 10B at the previous stage possibly leads to over input to the amplifier circuit 10C at the subsequent stage. Accordingly, the output power of the amplifier circuit 10A of the power amplifier circuit 1A with the two-stage configuration illustrated in FIG. 1A and the amplifier circuits 10A and 10B of the power amplifier circuit 1B with the three-stage configuration illustrated in FIG. 1B is required to be limited appropriately.

FIG. 2 is a view illustrating an example configuration of an amplifier circuit to which the limiter circuit according to the embodiment is applied. As illustrated in FIG. 2, the amplifier circuit 10 includes an amplifying transistor Tr1, a limiter circuit 3, and an input coupling capacitor Cin. The limiter circuit 3 includes a choke inductor L. The amplifier circuit 10 with the configuration illustrated in FIG. 2 is applied to the amplifier circuit 10A illustrated in FIG. 1A and the amplifier circuits 10A and 10B illustrated in FIG. 1B.

The amplifying transistor Tr1 amplifies an input signal RFin input from an input terminal 2a via the input coupling capacitor Cin and outputs an output signal RFout after the amplification from an output terminal 2b. The input coupling capacitor Cin blocks a direct-current component included in the input signal RFin.

The amplifying transistor Tr1 is, for example, a bipolar transistor. If the amplifying transistor Tr1 is formed from a bipolar transistor, for example, a heterojunction bipolar transistor (HBT) is exemplified. The amplifying transistor Tr1 may be formed from, for example, a field effect transistor (FET). The present disclosure is not limited to the configuration of the amplifying transistor Tr1.

Hereinafter, the example where the amplifying transistor Tr1 is a bipolar transistor will be described. In a case where the amplifying transistor Tr1 is formed from a FET, the emitter, the base, and the collector of the amplifying transistor Tr1 may be respectively read as the source, the gate, and the drain thereof.

The emitter (first terminal) of the amplifying transistor Tr1 is set to have a reference potential. The reference potential is herein a ground potential but is not limited to this.

The input coupling capacitor Cin (first coupling capacitor) is connected between the base (second terminal) of the amplifying transistor Tr1 and the input terminal 2a. A bias resistor Rb1 (first bias resistor) is connected between the base (second terminal) of the amplifying transistor Tr1 and a first bias voltage terminal 2c.

The input signal RFin is input to the amplifying transistor Tr1 via the input coupling capacitor Cin. A bias voltage Vb1 (first bias voltage) is supplied to the base (second terminal) of the amplifying transistor Tr1 via the bias resistor Rb1.

The collector (third terminal) of the amplifying transistor Tr1 is connected to the output terminal 2b. The output signal RFout of the amplifying transistor Tr1 is output from the output terminal 2b.

The limiter circuit 3 is connected to the collector (third terminal) of the amplifying transistor Tr1. A supply voltage Vcc (first supply voltage) is applied to the collector (third terminal) of the amplifying transistor Tr1 via the choke inductor L of the limiter circuit 3. In the present disclosure, the supply voltage Vcc is a variable voltage controlled based on the amplitude level or average output power of an input signal when the power amplifier circuit 1 amplifies power with the average power tracking (APT) system or the envelope tracking (ET) system. The choke inductor L has sufficiently high impedance for the transmission frequency band.

The limiter circuit 3 is a circuit that controls a voltage to be applied to the collector (third terminal) of the amplifying transistor Tr1 based on the power of the input signal RFin. Specifically, the limiter circuit 3 includes an input signal detection transistor Tr2 and a voltage limiting transistor Tr3 in addition to the choke inductor L.

The input signal detection transistor Tr2 and the voltage limiting transistor Tr3 are, for example, bipolar transistors. If the input signal detection transistor Tr2 and the voltage limiting transistor Tr3 are formed from the bipolar transistors, for example, a heterojunction bipolar transistor (HBT) is exemplified. The input signal detection transistor Tr2 and the voltage limiting transistor Tr3 may be formed from, for example, field effect transistors (FETs). The present disclosure is not limited to the configuration of the input signal detection transistor Tr2 and the voltage limiting transistor Tr3.

Hereinafter, the example where the input signal detection transistor Tr2 and the voltage limiting transistor Tr3 are bipolar transistors will be described. In the case where the input signal detection transistor Tr2 and the voltage limiting transistor Tr3 are formed from FETs, the emitter, the base, and the collector of each of the input signal detection transistor Tr2 and the voltage limiting transistor Tr3 may be respectively read as the source, the gate, and the drain thereof.

The emitter (first terminal) of the input signal detection transistor Tr2 is connected to a reference voltage terminal 2d. The potential of the reference voltage terminal 2d is herein the ground potential but is not limited to this.

A coupling capacitor C (second coupling capacitor) is connected between the base (second terminal) of the input signal detection transistor Tr2 and the input terminal 2a. A bias resistor Rb2 (second bias resistor) is connected between the base (second terminal) of the input signal detection transistor Tr2 and a second bias voltage terminal 2e. A bias voltage Vb2 is set to regulate a limiting characteristic in limiting a voltage to be applied to the collector (third terminal) of the amplifying transistor Tr1. The input signal RFin is input to a different one of ends of the coupling capacitor C.

The input signal RFin is input to the input signal detection transistor Tr2 via the coupling capacitor C (second coupling capacitor). The bias voltage Vb2 (second bias voltage) is supplied to the base (second terminal) of the input signal detection transistor Tr2 via the bias resistor Rb2.

An adjusting resistor R1 (first adjusting resistor) is connected between the collector (third terminal) of the input signal detection transistor Tr2 and a second supply voltage terminal 2f. A battery supply voltage Vbat (second supply voltage) is applied to the input signal detection transistor Tr2 via the adjusting resistor R1. In the present disclosure, the battery supply voltage Vbat is a predetermined fixed voltage supplied from a battery included, for example, in the wireless communication terminal. The resistance value of the adjusting resistor R1 is set to adjust a limiting characteristic in limiting a voltage to be applied to the collector (third terminal) of the amplifying transistor Tr1.

The base (second terminal) of the voltage limiting transistor Tr3 is connected to a connecting point between the collector (third terminal) of the input signal detection transistor Tr2 and the adjusting resistor R1.

The emitter (first terminal) of the voltage limiting transistor Tr3 is connected to the drain (third terminal) of the amplifying transistor Tr1. In other words, the emitter (first terminal) of the voltage limiting transistor Tr3 is connected to the output terminal 2b.

The choke inductor L is connected between the collector (third terminal) of the voltage limiting transistor Tr3 and a first supply voltage terminal 2g. The supply voltage Vcc (first supply voltage) is applied to the voltage limiting transistor Tr3 via the choke inductor L.

In the configuration described above, a voltage Vout to be applied to the collector (third terminal) of the amplifying transistor Tr1 is expressed by Formula (1) below. In Formula (1) below, Isense denotes current flowing to the input signal detection transistor Tr2, and Vth denotes a threshold voltage of the voltage limiting transistor Tr3.

Vout=Vbat−R1×Isense−Vth (1)

As expressed by Formula (1) above, the voltage Vout to be applied to the collector (third terminal) of the amplifying transistor Tr1 varies with the current Isense flowing to the input signal detection transistor Tr2.

In the present disclosure, the current Isense flowing to the input signal detection transistor Tr2 varies with the input signal RFin. Hereinafter, a method for setting the current Isense flowing to the input signal detection transistor Tr2 will be described.

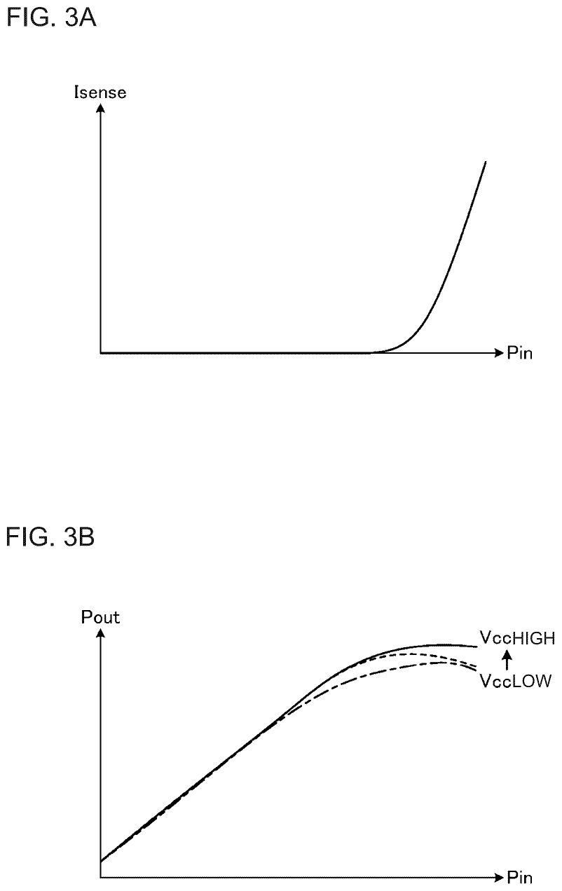

FIG. 3A is a graph illustrating an example of a characteristic of current flowing to the limiter circuit relative to the input power amplitude of an amplifying transistor. FIG. 3B is a graph illustrating an example of the input-output power characteristic of the amplifying transistor. In FIG. 3A, the horizontal axis represents input power Pin, and the vertical axis represents the current Isense flowing to the input signal detection transistor Tr2. In FIG. 3B, the horizontal axis represents the input power Pin, and the vertical axis represents output power Pout. The solid line illustrated in FIG. 3B represents the output power Pout in a case where the voltage value of the supply voltage Vcc (first supply voltage) is a, the broken line illustrated in FIG. 3B represents the output power Pout in a case where the voltage value of the supply voltage Vcc (first supply voltage) is b, and the alternate long and short dash line illustrated in FIG. 3B represents the output power Pout in a case where the voltage value of the supply voltage Vcc (first supply voltage) is c. The voltage values a, b, and c have the relationship a>b>c.

In the configuration of the embodiment illustrated in FIG. 2, the bias voltage Vb2 to be applied to the base (second terminal) of the input signal detection transistor Tr2 and the adjusting resistor R1 are adjusted, and setting is performed in an area where the input power Pin is relatively high to cause the current Isense to flow to the input signal detection transistor Tr2 in an area where the input power Pin is relatively high as illustrated in FIG. 3A. The voltage Vout to be applied to the collector (third terminal) of the amplifying transistor Tr1 is thereby decreased as illustrated in FIG. 3B. The output power Pout of the amplifier circuit 10 is thereby limited in an area where the input power Pin is relatively high.

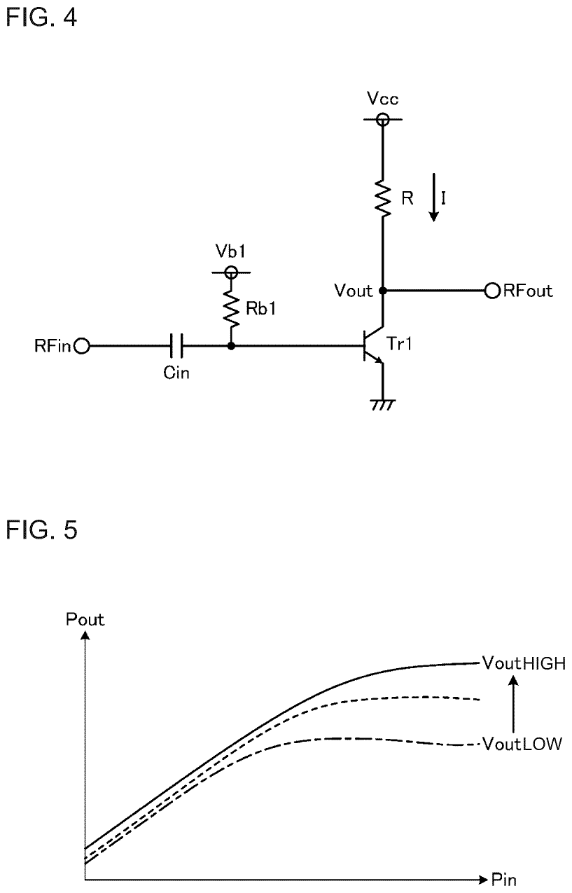

FIG. 4 is a graph illustrating an example configuration of an amplifier circuit according to a comparative example. In the comparative example illustrated in FIG. 4, a resistor R is provided instead of the limiter circuit 3. FIG. 5 is a graph illustrating an example of an input-output power characteristic of the amplifier circuit according to the comparative example. In the example illustrated in FIG. 5, the horizontal axis represents the input power Pin, and the vertical axis represents the output power Pout.

The solid line illustrated in FIG. 5 represents an input-output power ratio in the case where the voltage value of the supply voltage Vcc (first supply voltage) is a, the broken line illustrated in FIG. 5 represents an input-output power ratio in the case where the voltage value of the supply voltage Vcc (first supply voltage) is b, and the alternate long and short dash line illustrated in FIG. 5 represents an input-output power ratio in the case where the voltage value of the supply voltage Vcc (first supply voltage) is c. The voltage values a, b, and c of the supply voltage Vcc (first supply voltage) have the relationship a>b>c.

In the configuration in the comparative example illustrated in FIG. 4, the voltage Vout to be applied to the collector (third terminal) of the amplifying transistor Tr1 is expressed by Formula (2) below. In Formula (2) below, I denotes current flowing to the resistor R.

Vout=Vcc−R×I (2)

As expressed by Formula (2) above, in the configuration in the comparative example illustrated in FIG. 4, the voltage Vout to be applied to the collector (third terminal) of the amplifying transistor Tr1 varies in conjunction with the variation of the supply voltage Vcc. In conjunction with this, as illustrated in FIG. 5, the output power Pout largely varies in an area where the input power Pin is relatively high.

In the configuration of the embodiment illustrated in FIG. 2, as illustrated in FIG. 3B, variation of the output power Pout involved with variation of the supply voltage Vcc is reduced. In other words, it is possible to mitigate the degree of dependence of supply voltage variation on the output power Pout.

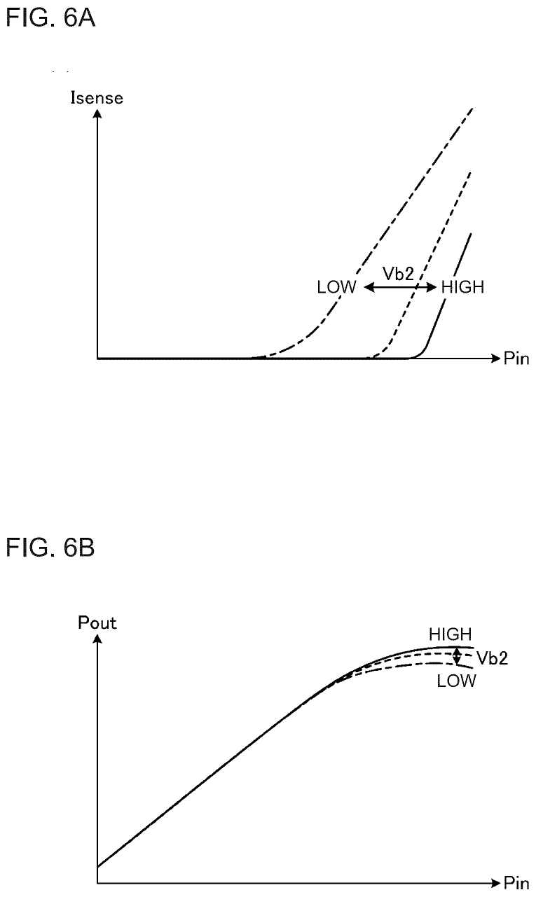

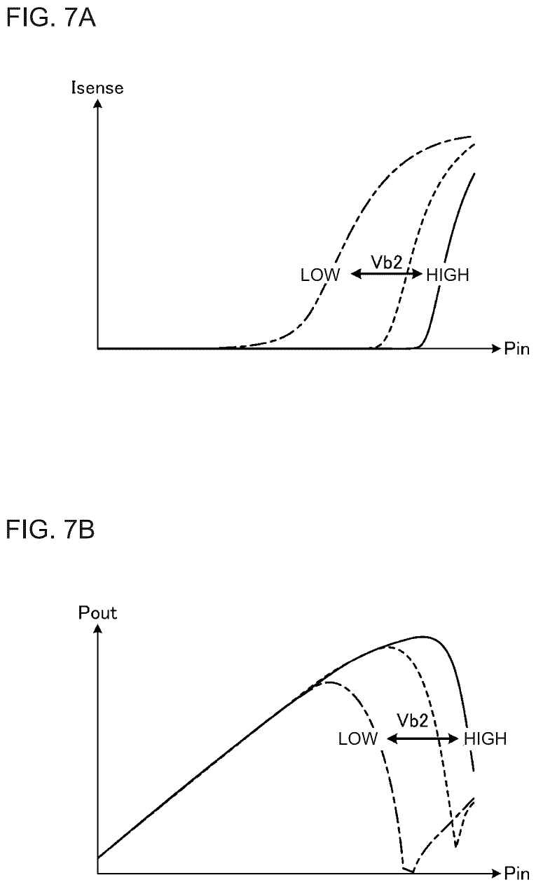

FIG. 6A and FIG. 6B are each a graph illustrating a first setting example of the limiting characteristic in the limiter circuit according to the embodiment. FIG. 7A and FIG. 7B are each a graph illustrating a second setting example of the limiting characteristic in the limiter circuit according to the embodiment. In FIG. 6A and FIG. 7A, the horizontal axis represents the input power Pin, and the vertical axis represents the current Isense flowing to the input signal detection transistor Tr2. In FIG. 6B and FIG. 7B, the horizontal axis represents the input power Pin, and the vertical axis represents the output power Pout.

The solid line illustrated in each of FIG. 6A and FIG. 6B represents the current Isense in a case where the voltage value of the bias voltage Vb2 (second bias voltage) is d, the broken line illustrated in each of FIG. 6A and FIG. 6B represents the current Isense in a case where the voltage value of the bias voltage Vb2 (second bias voltage) is e, and the alternate long and short dash line illustrated in each of FIG. 6A and FIG. 6B represents the current Isense in a case where the voltage value of the bias voltage Vb2 (second bias voltage) is f. The solid line illustrated in each of FIG. 7A and FIG. 7B represents an input-output power ratio in the case where the voltage value of the bias voltage Vb2 (second bias voltage) is d, the broken line illustrated in each of FIG. 7A and FIG. 7B represents an input-output power ratio in the case where the voltage value of the bias voltage Vb2 (second bias voltage) is e, and the alternate long and short dash line illustrated in each of FIG. 7A and FIG. 7B represents an input-output power ratio in the case where the voltage value of the bias voltage Vb2 (second bias voltage) is f. The voltage values d, e, and f of the bias voltage Vb2 (second bias voltage) have the relationship d>e>f.

In the configuration in the embodiment illustrated in FIG. 2, adjusting the bias voltage Vb2 to be applied to the base (second terminal) of the input signal detection transistor Tr2 and the adjusting resistor R1 enables limiting-characteristic setting in limiting the voltage to be applied to the collector (third terminal) of the amplifying transistor Tr1. Specifically, changing the level of a voltage to be output from the limiter circuit 3 enables setting for the limiting characteristic or a shutdown characteristic. A voltage value for the limiting characteristic is lower than a voltage value for the shutdown characteristic.

In the first setting example illustrated in FIG. 6A and FIG. 6B, it is possible to limit the output power Pout of the amplifier circuit 10 in an area where the input power Pin is relatively high. Specifically, in the first setting example illustrated in FIG. 6A and FIG. 6B, making variable the bias voltage Vb2 to be applied to the base (second terminal) of the input signal detection transistor Tr2 enables an amount of suppressing the output power Pout of the amplifier circuit 10 to be controlled.

In the second setting example illustrated in FIG. 7A and FIG. 7B, it is possible to shut down the output power Pout of the amplifier circuit 10 (have a certain value or lower) in an area where the input power Pin is relatively high. Specifically, in the second setting example illustrated in FIG. 7A and FIG. 7B, making variable the bias voltage Vb2 to be applied to the base (second terminal) of the input signal detection transistor Tr2 enables the input power Pin for shutting down the output power Pout of the amplifier circuit 10 to be controlled.

### First Modification

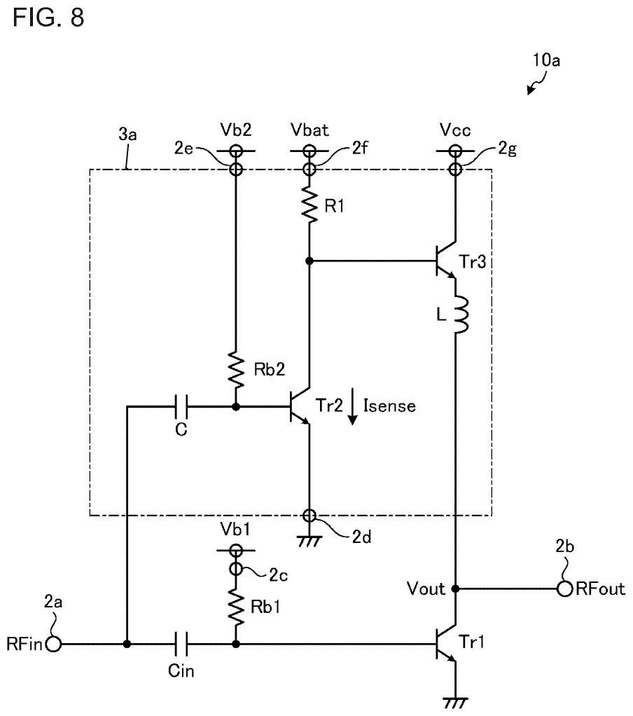

FIG. 8 is a view illustrating an example configuration of an amplifier circuit to which a limiter circuit according to a first modification of the embodiment is applied. As illustrated in FIG. 8, the choke inductor L of a limiter circuit 3a of an amplifier circuit 10a is provided between the emitter (first terminal) of the voltage limiting transistor Tr3 and the collector (third terminal) of the amplifying transistor Tr1. In other words, the choke inductor L is connected between the emitter (first terminal) of the voltage limiting transistor Tr3 and the output terminal 2b. This enables high impedance to be provided at the limiter circuit 3a viewed from the amplifying transistor Tr1. This enables load on a matching circuit connected at the subsequent stage to be less influenced and enables the characteristic of the amplifying transistor Tr1 to be less influenced.

### Second Modification

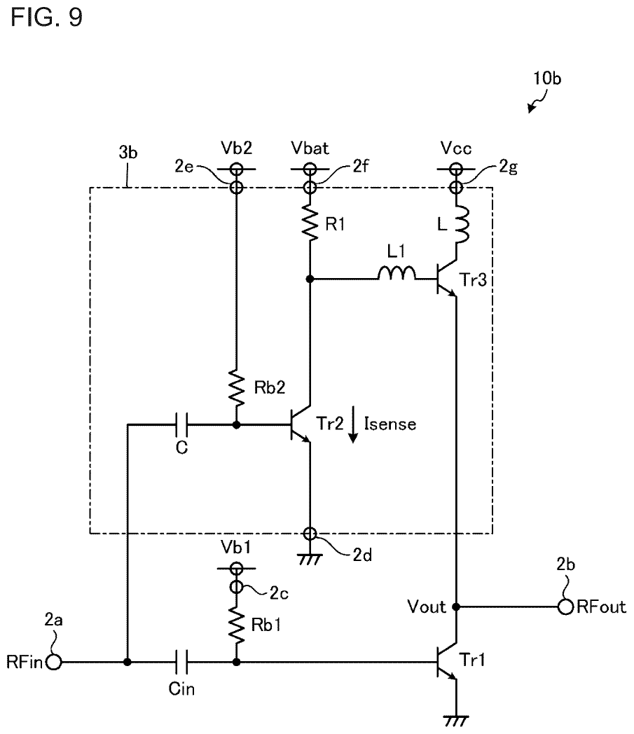

FIG. 9 is a view illustrating an example configuration of an amplifier circuit to which a limiter circuit according to a second modification of the embodiment is applied. As illustrated in FIG. 9, a limiter circuit 3b of an amplifier circuit 10b is provided with an inductor L1 on a path connecting to the base (second terminal) of the voltage limiting transistor Tr3. In other words, the inductor L1 is connected between the base (second terminal) of the voltage limiting transistor Tr3 and a connecting point between the collector (third terminal) of the input signal detection transistor Tr2 and the adjusting resistor R1. Like the first modification, this enables high impedance to be provided at the limiter circuit 3b viewed from the amplifying transistor Tr1. Like the first modification, this enables load on a matching circuit connected at the subsequent stage to be less influenced and enables the characteristic of the amplifying transistor Tr1 to be less influenced.

### Third Modification

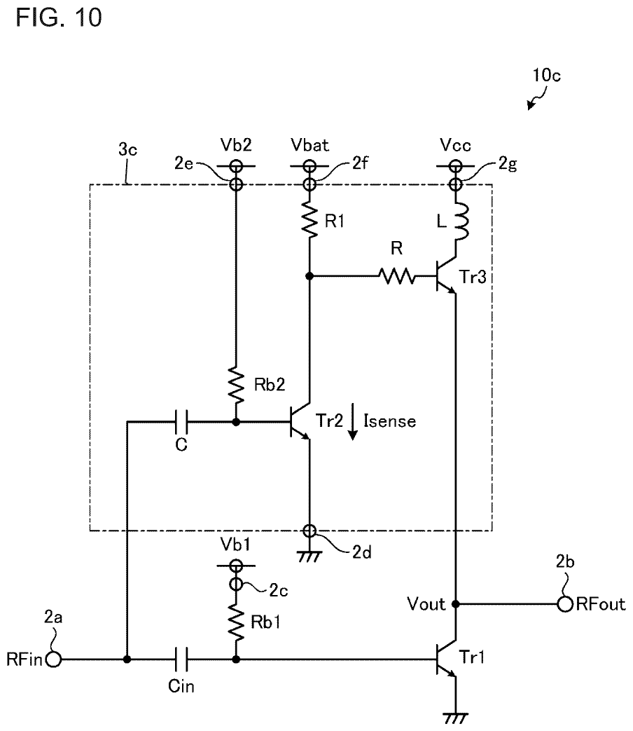

FIG. 10 is a view illustrating an example configuration of an amplifier circuit to which a limiter circuit according to a third modification of the embodiment is applied. As illustrated in FIG. 10, a limiter circuit 3c of an amplifier circuit 10c is provided with the resistor R (resistor) instead of the inductor L1 in the second modification on a path connecting to the base (second terminal) of the voltage limiting transistor Tr3. In other words, the resistor R (resistor) is connected between the base (second terminal) of the voltage limiting transistor Tr3 and a connecting point between the collector (third terminal) of the input signal detection transistor Tr2 and the adjusting resistor R1. Like the first modification and the second modification, this enables high impedance to be provided at the limiter circuit 3c viewed from the amplifying transistor Tr1. Like the first modification, this enables load on a matching circuit connected at the subsequent stage to be less influenced and enables the characteristic of the amplifying transistor Tr1 to be less influenced.

### Fourth Modification

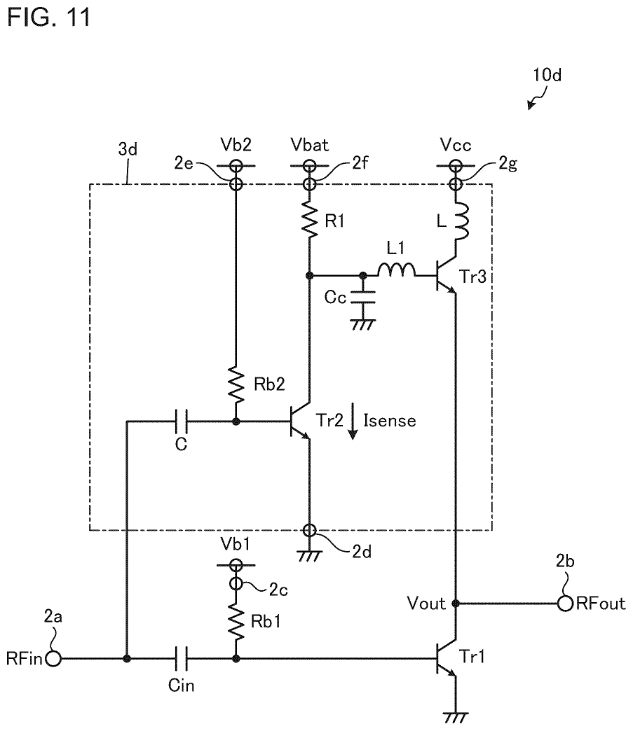

FIG. 11 is a view illustrating an example configuration of an amplifier circuit to which a limiter circuit according to a fourth modification of the embodiment is applied. As illustrated in FIG. 11, a limiter circuit 3d of an amplifier circuit 10d is provided with a capacitor Cc connected to the collector (third terminal) of the input signal detection transistor Tr2 at the ground potential, in addition to the inductor L1 in the second modification. The capacitor Cc connected at the ground potential and the inductor L1 form an LC filter. In other words, the LC filter is connected between the base (second terminal) of the voltage limiting transistor Tr3 and a connecting point between the collector (third terminal) of the input signal detection transistor Tr2 and the adjusting resistor R1. This enables an output signal output from the amplifying transistor Tr1 to be prevented from leaking to the voltage limiting transistor Tr3 and enables a radio frequency signal component amplified by the voltage limiting transistor Tr3 to be attenuated by using the LC filter.

### Fifth Modification

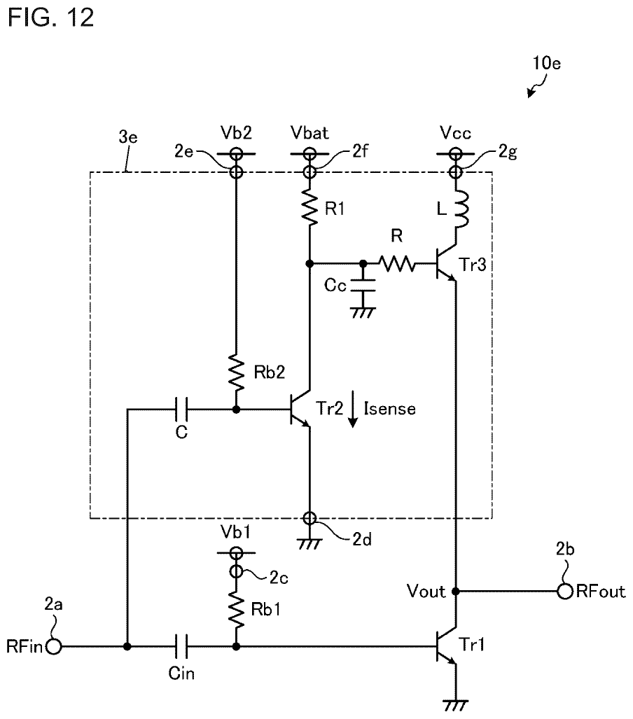

FIG. 12 is a view illustrating an example configuration of an amplifier circuit to which a limiter circuit according to a fifth modification of the embodiment is applied. As illustrated in FIG. 12, a limiter circuit 3e of an amplifier circuit 10e is provided with the capacitor Cc connected to the collector (third terminal) of the input signal detection transistor Tr2 at the ground potential, in addition to the resistor R in the third modification. The capacitor Cc connected at the ground potential and the resistor R form an RC filter. In other words, the RC filter is connected between the base (second terminal) of the voltage limiting transistor Tr3 and a connecting point between the collector (third terminal) of the input signal detection transistor Tr2 and the adjusting resistor R1. This enables an output signal output from the amplifying transistor Tr1 to be prevented from leaking to the voltage limiting transistor Tr3 and enables a radio frequency signal component amplified by the voltage limiting transistor Tr3 to be attenuated by using the RC filter.

### Sixth Modification

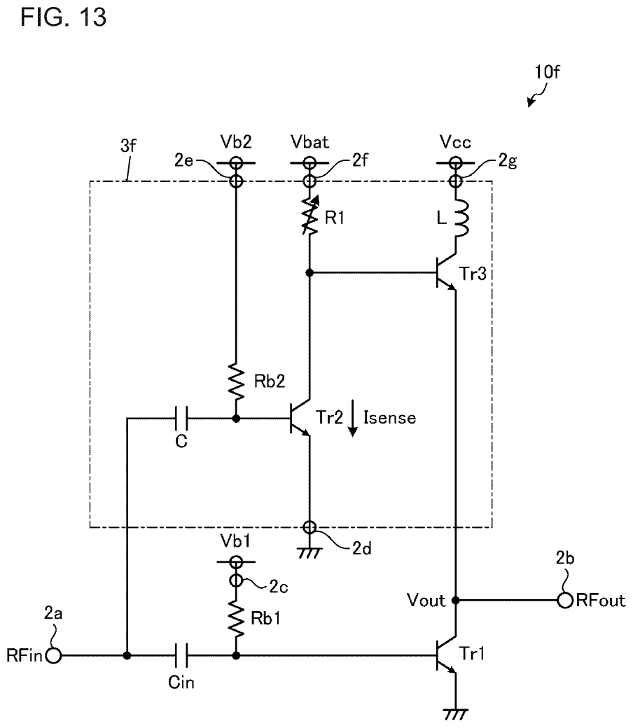

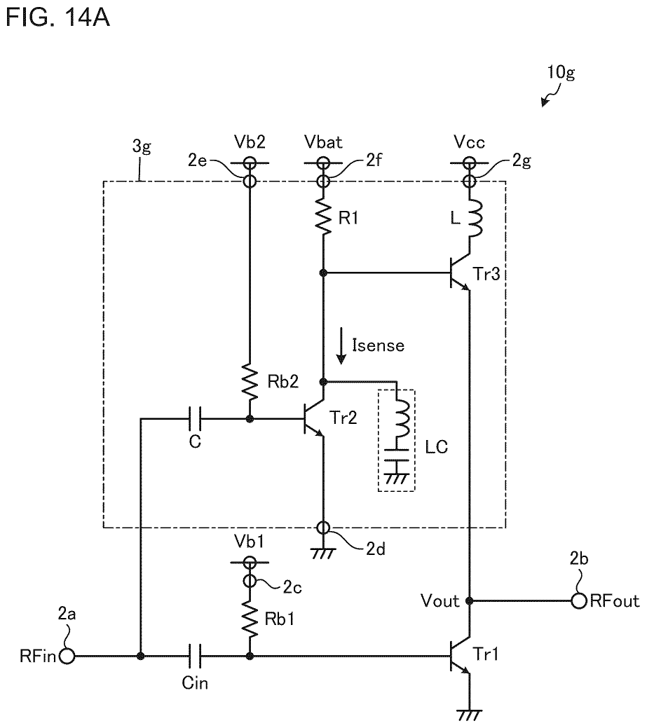

FIG. 13 is a view illustrating an example configuration of an amplifier circuit to which a limiter circuit according to a sixth modification of the embodiment is applied. As illustrated in FIG. 13, the adjusting resistor R1 may be a variable resistor. As the variable resistor, for example, a ladder resistor and a switch provided to a power amplifier IC are exemplified. This facilitates limiting-characteristic setting in a limiter circuit 3f of an amplifier circuit 10f.

### Seventh Modification

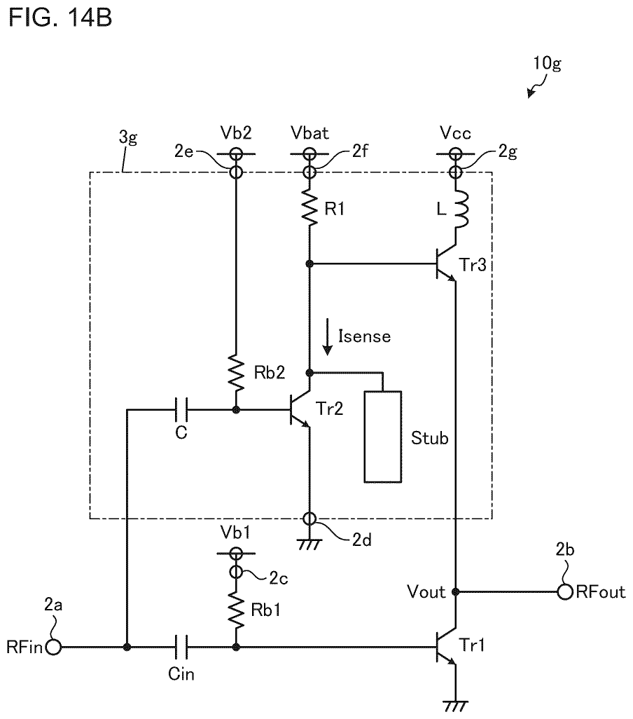

FIG. 14A and FIG. 14B are each a view illustrating an example configuration of an amplifier circuit to which a limiter circuit according to a seventh modification of the embodiment is applied. As illustrated in FIG. 14A and FIG. 14B, in a limiter circuit 3g of an amplifier circuit 10g, a harmonic termination circuit is connected to the collector (third terminal) of the input signal detection transistor Tr2. FIG. 14A illustrates an example where an LC series circuit as a harmonic termination circuit is connected to the collector (third terminal) of the input signal detection transistor Tr2. FIG. 14B illustrates an example where a stub Stub as a harmonic termination circuit is connected to the collector (third terminal) of the input signal detection transistor Tr2.

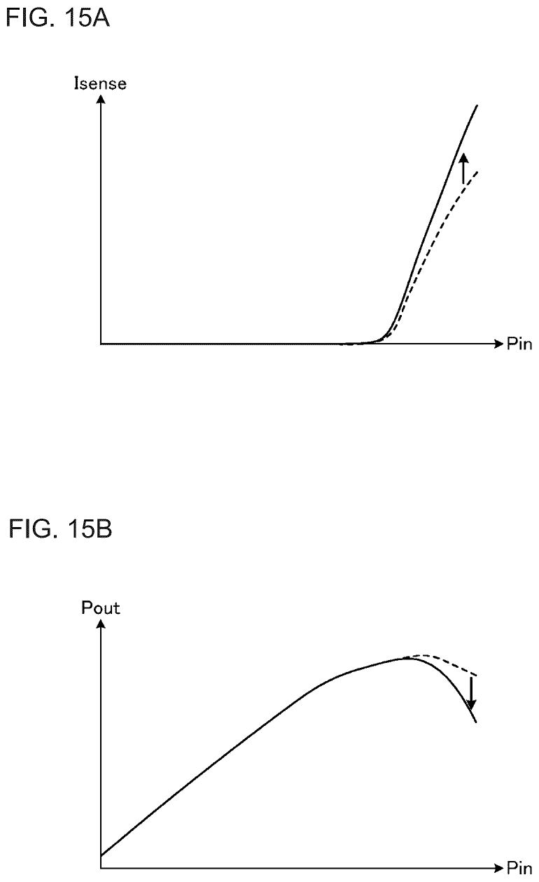

FIG. 15A and FIG. 15B are each a graph illustrating an improvement example of the limiting characteristic in the limiter circuit according to the seventh modification of the embodiment. In FIG. 15A, the horizontal axis represents the input power Pin, and the vertical axis represents the current Isense flowing to the input signal detection transistor Tr2. In FIG. 15B, the horizontal axis represents the input power Pin, and the vertical axis represents the output power Pout.

The solid line illustrated in FIG. 15A represents the current Isense in a case where a harmonic termination circuit is provided to the collector (third terminal) of the input signal detection transistor Tr2, and the broken line illustrated in FIG. 15A represents the current Isense in a case where the harmonic termination circuit is not provided to the collector (third terminal) of the input signal detection transistor Tr2. The solid line illustrated in FIG. 15B represents an input-output power ratio in the case where the harmonic termination circuit is provided to the collector (third terminal) of the input signal detection transistor Tr2, and the broken line illustrated in FIG. 15B represents an input-output power ratio in the case where the harmonic termination circuit is not provided to the collector (third terminal) of the input signal detection transistor Tr2.

As illustrated in FIG. 15A and FIG. 15B, providing the harmonic termination circuit to the collector (third terminal) of the input signal detection transistor Tr2 enables the limiting characteristic in the limiter circuit 3g of the amplifier circuit 10g to be improved.

### Eighth Modification

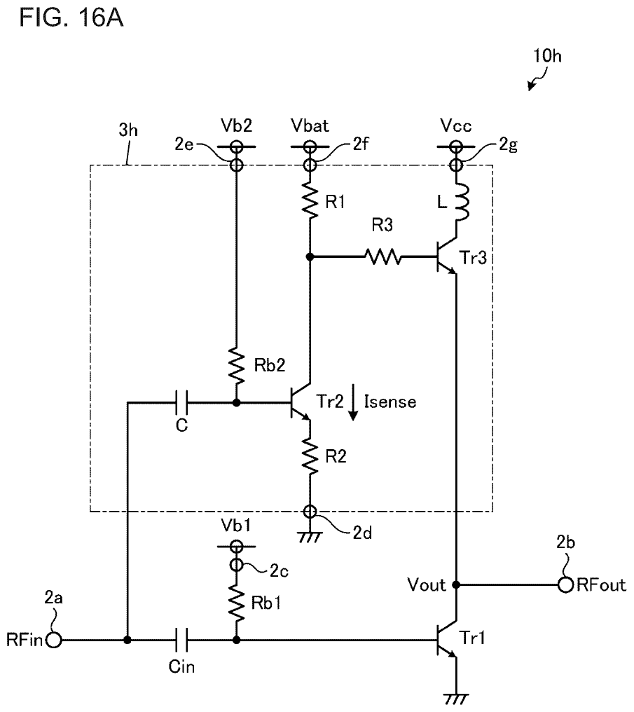

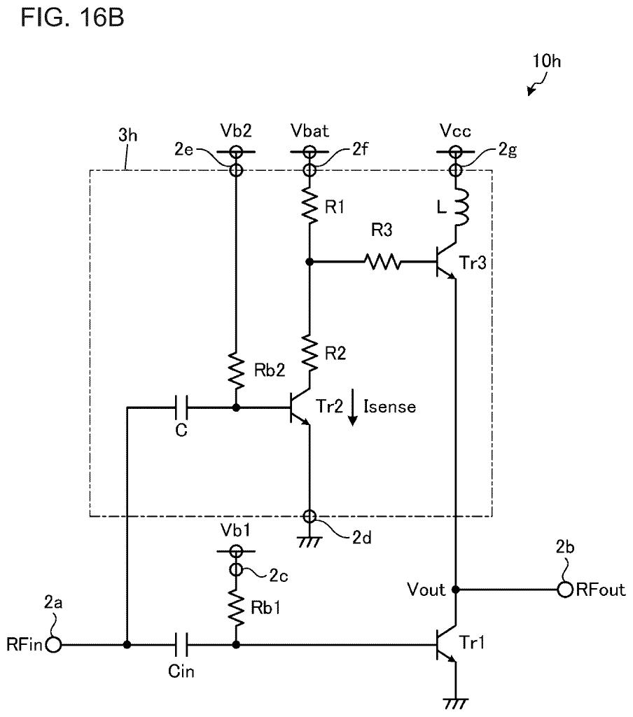

FIG. 16A and FIG. 16B are each a view illustrating an example configuration of an amplifier circuit to which a limiter circuit according to an eighth modification of the embodiment is applied. As illustrated in FIG. 16A, a limiter circuit 3h of an amplifier circuit 10h may be in a form in which the emitter (first terminal) of the input signal detection transistor Tr2 is grounded with an adjusting resistor R2 (second adjusting resistor) interposed therebetween and in which the base (second terminal) of the voltage limiting transistor Tr3 is connected to a connecting point between the collector (third terminal) of the input signal detection transistor Tr2 and the adjusting resistor R1 with an adjusting resistor R3 (third adjusting resistor) interposed therebetween. In addition, as illustrated in FIG. 16B, the limiter circuit 3h of the amplifier circuit 10h may be in a form in which the adjusting resistor R2 is provided between the collector (third terminal) of the input signal detection transistor Tr2 and the adjusting resistor R1 and in which the base (second terminal) of the voltage limiting transistor Tr3 is connected to a connecting point between the collector (third terminal) of the input signal detection transistor Tr2 and the adjusting resistor R2 with the adjusting resistor R3 interposed therebetween. It is thereby possible to suppress a rise in a voltage across the collector (third terminal) and the emitter (first terminal) of the input signal detection transistor Tr2 (a drain-source voltage of the input signal detection transistor Tr2 if the input signal detection transistor Tr2 is formed from a FET).

Applying each of the amplification devices according to the embodiment and the modifications that are described above to, for example, the amplifier circuit 10A in the power amplifier circuit illustrated in FIG. 1A enables over input to the amplifier circuit 10B at the subsequent stage to be prevented. Applying the amplification device according to the embodiment and the modifications that are described above to, for example, the amplifier circuit 10A in the power amplifier circuit illustrated in FIG. 1B also enables over input to the amplifier circuit 10B at the subsequent stage to be prevented. Applying the amplification device according to the embodiment and the modifications that are described above to, for example, the amplifier circuit 10B in the power amplifier circuit illustrated in FIG. 1B also enables over input to the amplifier circuit 10C at the subsequent stage to be prevented.

The embodiment and the modifications that are described above are provided for easier understanding of the present disclosure and is not intended to limit the interpretation of the present disclosure. The present disclosure may be changed/improved without necessarily departing from the spirit thereof and includes its equivalents.

The present disclosure may have the following configurations as described above or instead of the description above.

(1) A limiter circuit according to an aspect of the present disclosure is connectable to an amplifying transistor that amplifies and outputs a radio frequency signal, the limiter circuit controlling a voltage to be applied to the amplifying transistor, the limiter circuit controlling the voltage based on the radio frequency signal. The limiter circuit includes: an input signal detection transistor that detects power of the radio frequency signal; and a voltage limiting transistor that limits the voltage to be applied to the amplifying transistor, the voltage limiting transistor limiting the voltage based on current flowing to the input signal detection transistor.

This configuration enables the output power of the amplifying transistor to be effectively limited based on the amplitude of the input signal.

(2) A limiter circuit according to an aspect of the present disclosure includes: an input terminal; an output terminal; an input signal detection transistor that is electrically connected to the input terminal and that detects power of a radio frequency signal; and a voltage limiting transistor having a first terminal electrically connected to the output terminal and a third terminal electrically connected to a first supply voltage terminal. An amplifying transistor that amplifies and outputs a radio frequency signal is connectable between the input terminal and the output terminal.

This configuration enables the output power of the amplifying transistor to be effectively limited based on the amplitude of the input signal.

(3) In the limiter circuit according to (2) above, the first terminal of the voltage limiting transistor is connected to the output terminal. A choke inductor is connected between a third terminal of the voltage limiting transistor and the first supply voltage terminal. A first terminal of the input signal detection transistor is electrically connected to a reference voltage terminal. A second coupling capacitor is connected between a second terminal of the input signal detection transistor and the input terminal. A second bias resistor is connected between the second terminal of the input signal detection transistor and a second bias voltage terminal. A first adjusting resistor is connected between a third terminal of the input signal detection transistor and a second supply voltage terminal. The second terminal of the voltage limiting transistor is connected to a connecting point between a third terminal of the input signal detection transistor and the first adjusting resistor.

This configuration enables the output power to be limited based on the amplitude of the input radio frequency signal.

(4) In the limiter circuit according to (2) above, a choke inductor is connected between the first terminal of the voltage limiting transistor and the output terminal. A third terminal of the voltage limiting transistor is connected to the first supply voltage terminal. A first terminal of the input signal detection transistor is grounded. A second coupling capacitor is connected between a second terminal of the input signal detection transistor and the input terminal. A second bias resistor is connected between the second terminal of the input signal detection transistor and a second bias voltage terminal. A first adjusting resistor is connected between a third terminal of the input signal detection transistor and a second supply voltage terminal. The second terminal of the voltage limiting transistor is connected to a connecting point between a third terminal of the input signal detection transistor and the first adjusting resistor.

This configuration enables the output power to be limited based on the amplitude of the input radio frequency signal. It is also possible to provide high impedance at the limiter circuit viewed from the amplifying transistor, by using the choke inductor.

(5) In the limiter circuit according to (3) above, an inductor is further connected between the second terminal of the voltage limiting transistor and the connecting point between the third terminal of the input signal detection transistor and the first adjusting resistor.

This configuration enables the output power to be limited based on the amplitude of the input radio frequency signal. It is also possible to provide high impedance at the limiter circuit viewed from the amplifying transistor, by using the inductor.

(6) In the limiter circuit according to (3) above, a resistor is further connected between the second terminal of the voltage limiting transistor and the connecting point between the third terminal of the input signal detection transistor and the first adjusting resistor.

This configuration enables the output power to be limited based on the amplitude of the input radio frequency signal. It is also possible to provide high impedance at the limiter circuit viewed from the amplifying transistor, by using the resistor.

(7) In the limiter circuit according to (3) above, an LC filter is further connected between the second terminal of the voltage limiting transistor and the connecting point between the third terminal of the input signal detection transistor and the first adjusting resistor.

This configuration enables the output power to be limited based on the amplitude of the input radio frequency signal. It is also possible to cause the fluctuation component of the radio frequency signal amplified by the voltage limiting transistor to be attenuated by using the LC filter.

(8) In the limiter circuit according to (3) above, an RC filter is further connected between the second terminal of the voltage limiting transistor and the connecting point between the third terminal of the input signal detection transistor and the first adjusting resistor.

This configuration enables the output power to be limited based on the amplitude of the input radio frequency signal. It is also possible to cause the fluctuation component of the radio frequency signal amplified by the voltage limiting transistor to be attenuated by using the RC filter.

(9) In the limiter circuit according to (3) above, a second adjusting resistor is further connected between the first terminal of the input signal detection transistor and the reference voltage terminal. A third adjusting resistor is further connected between the second terminal of the voltage limiting transistor and the connecting point between the third terminal of the input signal detection transistor and the first adjusting resistor.

This configuration enables the output power to be limited based on the amplitude of the input radio frequency signal. It is also possible to suppress voltage rise between the third terminal and the first terminal of the input signal detection transistor.

(10) The limiter circuit according to (3) above further includes: a second adjusting resistor between the third terminal of the input signal detection transistor and the first adjusting resistor. The third adjusting resistor is further connected between the second terminal of the voltage limiting transistor and a connecting point between the first adjusting resistor and the second adjusting resistor.

This configuration enables the output power to be limited based on the amplitude of the input radio frequency signal. It is also possible to suppress voltage rise between the third terminal and the first terminal of the input signal detection transistor.

(11) In the limiter circuit according to any one of (3) to (10) above, a harmonic termination circuit is connected to the third terminal of the input signal detection transistor.

This configuration enables the output power to be limited based on the amplitude of the input radio frequency signal. It is also possible to improve a limiting characteristic in the limiter circuit by performing the harmonic termination on the third terminal of the input signal detection transistor.

(12) In the limiter circuit according to (11) above, the harmonic termination circuit is an LC series resonance circuit.

This configuration enables the output power to be limited based on the amplitude of the input radio frequency signal. It is also possible to improve the limiting characteristic in the limiter circuit by performing the harmonic termination on the third terminal of the input signal detection transistor by using the LC series circuit.

(13) In the limiter circuit according to (11) above, the harmonic termination circuit is a stub.

This configuration enables the output power to be limited based on the amplitude of the input radio frequency signal. It is also possible to improve the limiting characteristic in the limiter circuit by performing the harmonic termination on the third terminal of the input signal detection transistor by using the stub.

(14) In the limiter circuit according to any one of (3) to (13) above, the first adjusting resistor is a variable resistor.

This configuration facilitates limiting-characteristic setting in the limiter circuit.

(15) In the limiter circuit according to any one of (3) to (14) above, a voltage supplied from the first supply voltage terminal is a variable voltage controlled based on an amplitude level of the radio frequency signal or average output power of the radio frequency signal. A voltage supplied from the second supply voltage terminal is a predetermined fixed voltage.

According to the present disclosure, it is possible to provide a limiter circuit capable of effectively limiting the output power of the amplifying transistor based on the amplitude of the input signal.

(16) A power amplifier circuit according to an aspect of the present disclosure includes: the limiter circuit according to any one of (2) to (15) above; and an amplifying transistor that is provided between the input terminal and the output terminal and that amplifies and outputs a radio frequency signal.

This configuration enables over input to a circuit at the subsequent stage to be prevented.

(17) A power amplifier circuit according to an aspect of the present disclosure is a power amplifier circuit in which a plurality of amplifier circuits are connected in a multi-stage connection configuration. At least one of the plurality of amplifier circuits except an amplifier circuit at a last stage includes: the limiter circuit according to any one of (2) to (15) above; and an amplifying transistor that is provided between the input terminal and the output terminal and that amplifies and outputs a radio frequency signal.

According to this configuration, it is possible to prevent over input to the amplifier circuit at the subsequent stage of the amplifier circuit including the limiter circuit.

(18) In the power amplifier circuit according to (16) or (17) above, in the amplifying transistor, a first terminal is grounded, a first coupling capacitor is connected between a second terminal and the input terminal, a second bias resistor is connected between the second terminal and a second bias voltage terminal, and a third terminal is connected to the output terminal.

According to the present disclosure, it is possible to provide a power amplifier circuit capable of effectively limiting the output power of the amplifying transistor based on the amplitude of the input signal.

### REFERENCE SIGNS LIST

1, 1A, 1B power amplifier circuit
2a input terminal
2b output terminal
2c first bias voltage terminal
2d reference voltage terminal
2e second bias voltage terminal
2f second supply voltage terminal
2g first supply voltage terminal
3, 3a, 3b, 3c, 3d, 3e, 3f, 3g, 3h limiter circuit
10, 10A, 10B, 10C, 10a, 10b, 10c, 10d, 10e, 10f, 10g, 10h amplifier circuit
C coupling capacitor (second coupling capacitor)
Cc capacitor
Cin input coupling capacitor (first coupling capacitor)
L choke inductor
L1 inductor
R resistance
R1 adjusting resistor (first adjusting resistor)
R2 adjusting resistor (second adjusting resistor)
R3 adjusting resistor (third adjusting resistor)
Rb1 bias resistor (first bias resistor)
RFin input signal
RFout output signal
Stub stub
Tr1 amplifying transistor
Tr2 input signal detection transistor
Tr3 voltage limiting transistor
Vb1 bias voltage (first bias voltage)
Vb2 bias voltage (second bias voltage)
Vbat battery supply voltage (second supply voltage)
Vcc supply voltage (first supply voltage)

1. A limiter circuit connected to an amplifying transistor that amplifies and outputs a radio frequency signal, the limiter circuit being configured to control a voltage applied to the amplifying transistor based on the radio frequency signal, the limiter circuit comprising:
an input signal detection transistor configured to detect a power of the radio frequency signal; and
a voltage limiting transistor configured to limit the voltage applied to the amplifying transistor based on a current flowing to the input signal detection transistor.

2. A limiter circuit comprising:
an input terminal;
an output terminal;
an input signal detection transistor that is electrically connected to the input terminal and that is configured to detect a power of a radio frequency signal; and
a voltage limiting transistor having a first terminal that is electrically connected to the output terminal, and a third terminal electrically connected to a first supply voltage terminal,
wherein an amplifying transistor configured to amplify and output a radio frequency signal is connected between the input terminal and the output terminal.

3. The limiter circuit according to claim 2,
wherein a choke inductor is connected between the third terminal of the voltage limiting transistor and the first supply voltage terminal,
wherein a first terminal of the input signal detection transistor is electrically connected to a reference voltage terminal,
wherein a second coupling capacitor is connected between a second terminal of the input signal detection transistor and the input terminal,
wherein a second bias resistor is connected between the second terminal of the input signal detection transistor and a second bias voltage terminal,
wherein a first adjusting resistor is connected between a third terminal of the input signal detection transistor and a second supply voltage terminal, and
wherein the second terminal of the voltage limiting transistor is connected to a first node that is between the third terminal of the input signal detection transistor and the first adjusting resistor.

4. The limiter circuit according to claim 2,
wherein a choke inductor is connected between the first terminal of the voltage limiting transistor and the output terminal,
wherein a first terminal of the input signal detection transistor is grounded,
wherein a second coupling capacitor is connected between a second terminal of the input signal detection transistor and the input terminal,
wherein a second bias resistor is connected between the second terminal of the input signal detection transistor and a second bias voltage terminal,
wherein a first adjusting resistor is connected between a third terminal of the input signal detection transistor and a second supply voltage terminal, and
wherein the second terminal of the voltage limiting transistor is connected to a first node that is between the third terminal of the input signal detection transistor and the first adjusting resistor.

5. The limiter circuit according to claim 3, further comprising:
an inductor connected between the second terminal of the voltage limiting transistor and the first node.

6. The limiter circuit according to claim 3, further comprising:
a resistor connected between the second terminal of the voltage limiting transistor and the first node.

7. The limiter circuit according to claim 3, further comprising:
an LC filter connected between the second terminal of the voltage limiting transistor and the first node.

8. The limiter circuit according to claim 3, further comprising:
an RC filter connected between the second terminal of the voltage limiting transistor and the first node.

9. The limiter circuit according to claim 3, further comprising:
a second adjusting resistor connected between the first terminal of the input signal detection transistor and the reference voltage terminal, and
a third adjusting resistor connected between the second terminal of the voltage limiting transistor and the first node.

10. The limiter circuit according to claim 3, further comprising:
a second adjusting resistor between the third terminal of the input signal detection transistor and the first adjusting resistor; and
a third adjusting resistor connected between the second terminal of the voltage limiting transistor and a second node that is between the first adjusting resistor and the second adjusting resistor.

11. The limiter circuit according to claim 3, further comprising:
a harmonic termination circuit connected to the third terminal of the input signal detection transistor.

12. The limiter circuit according to claim 11, wherein the harmonic termination circuit is an LC series resonance circuit.

13. The limiter circuit according to claim 11, wherein the harmonic termination circuit is a stub.

14. The limiter circuit according to claim 3, wherein the first adjusting resistor is a variable resistor.

15. The limiter circuit according to claim 3,
wherein a voltage supplied from the first supply voltage terminal is variable based on an amplitude level of the radio frequency signal or based on an average output power of the radio frequency signal, and
wherein a voltage supplied from the second supply voltage terminal is predetermined and fixed.

16. A power amplifier circuit comprising:
the limiter circuit according to claim 2; and
the amplifying transistor that is between the input terminal and the output terminal, and that is configured to amplify and to output the radio frequency signal.

17. A power amplifier circuit, comprising:
a plurality of amplifier circuits connected in a multi-stage configuration,
wherein at least one of the plurality of amplifier circuits other than a final stage amplifier circuit comprises:
the limiter circuit according to claim 2; and
the amplifying transistor that is between the input terminal and the output terminal, and that is configured to amplify and to output the radio frequency signal.

18. The power amplifier circuit according to claim 16, wherein in the amplifying transistor:
a first terminal is grounded,
a first coupling capacitor is connected between a second terminal and the input terminal,
a second bias resistor is connected between the second terminal and a second bias voltage terminal, and
a third terminal is connected to the output terminal.
